(19) United States
(12) Patent Application Publication
(10) Pub. No.: US 2008/0280652 A1
(43) Pub. Date: Nov. 13, 2008

(54) RECONFIGURABLE KEYPAD METHOD IN HANDSET DEVICE OPERABLE WITH PLURAL SUBSYSTEMS

(75) Inventors: Patrick J. Marry, Lincolnshire, IL (US); Donald L. Deubler, JR., Chicago, IL (US)

Correspondence Address: PERRY HOFFMAN & ASSOCIATES P.C., PO BOX 1649, DEERFIELD, IL, 60015, US

(73) Assignee: FIREFLY MOBILE, INC., Lincolnshire, IL (US)

(21) Appl. No.: 11/944,175

(22) Filed: Nov. 21, 2007

Related U.S. Application Data
(60) Provisional application No. 60/916,623, filed on May 8, 2007.

(51) Int. Cl. H04M 1/00; G06F 3/02; H03K 17/94

(52) U.S. Cl. 455/566; 345/169; 341/23

(57) ABSTRACT

A user input device is provided that permits multiple functions to be implemented in a confined space using key images defined by a reconfigurable backlight structure under automatic software control. The keypads change automatically depending on what the user is doing with the device. By selectively illuminating one of several key images at each key location, widely varying keypad functionality can be realized without increased the size of the keypad or the number of key locations.

### CROSS-REFERENCE TO RELATED APPLICATION

This application claims priority pursuant to 35 U.S.C. 119(e) to U.S. Provisional Application No. 60/916,623, filed on May 8, 2007 which is incorporated herein by reference in its entirety.

### BACKGROUND OF THE INVENTION

1. Field of the Invention

The present invention relates a user input device for small, portable electronics that permits multiple functions to be implemented in a confined space using key images defined by a reconfigurable backlight structure under automatic software control.

2. Description of the Related Art

The consumer electronics industry faces the continuing trends of adding more functionality to consumer devices while at the same time enabling these devices to be physically smaller through the benefits of semiconductor integration. These industry trends, more functionality in a smaller size, have lead to undesirable compromises in keypad design; large keypad areas with an increasing number of very small keys. In many cases the physical size of keys has become too small to be useful for the average user. Purchase decisions are increasingly driven by “ease of use” with larger keys playing an ever increasing role in this decision.

U.S. Pat. No. 4,746,919 to Reitmeier for “Remote control system with key function display provisions” issued May 24, 1988 describes a transmitter unit of a remote control system that includes a key function display unit for identifying the function of key elements of the transmitter unit at various steps of a control sequence for one or more controlled devices. The memory for storing character-representative information for identifying the functions of the key elements of the transmitter and corresponding function control instructions is contained in the controlled devices rather than in the transmitter unit, which allows for the addition of new controlled device without modification of the transmitter units. It is known to utilize electroluminescent (EL) display segments in remote control devices and the like for controlling the operation of various appliances, for example U.S. Pat. No. 7,013,434 to Masters et al. for “Remote control with local, screen-guided setup” issued Mar. 14, 2006 relates to a universal remote control having an EL display where various segments of the EL display are illuminated under user control at various times to present the user with a remote control user interface that corresponds to an activity currently being performed by the user. While EL displays and backlights are well-known in the consumer electronics industry, with EL backlights being very common in cellular telephones in particular, a need exists to provide improved user input devices in keypad device operation and the like.

The present invention relates to user input devices in general and, in particular, keypads in which the image of each key is created using an electroluminescent (EL) panel.

### SUMMARY OF THE INVENTION

It is a general object of the invention to provide an improved reconfigurable keypad method in a handset device having a display on its housing with the handset device being operable with a plurality of subsystems, which avoids the disadvantages of the prior art while affording additional operating advantages.

To this end, a reconfigurable keypad as the user input device of a cellular telephone, remote control or other consumer electronics application. The goal is to create multiple keypad configurations with the minimum number of large keys. In previous implementations this added functionality is provided by adding keys to a conventional keypad, making the product less user friendly as additional keys are added. This invention eliminates this problem.

For the case of a cellular telephone of the current implementation, three operating modes have been identified:

1. Telephone dialing, using a conventional 3×4 grid of keys,
2. Navigation Mode in which menus or lists need to be quickly reviewed with a particular item being highlighted in the list, then selected,
3. Media player in which additional functions such as Play/Pause, Fast Forward and Rewind are implemented as dedicated keys.

These operating modes enable multiple functions of the device, including

1. telephone
2. camera with zoom in/out, shutter
3. game controller
4. music player
5. video player

The operating modes can be implemented with a minimum of 12 key locations. Each key location includes a popple, a metal dome that provides mechanical feedback and acts as an electrical switch to indicate when a key is depressed by the user. A segmented EL panel covers the popples. The EL panel contains multiple patterns which form the user-perceived key functions. Each pattern can define an entire operating mode by including all necessary images required by the mode, or it may contain only a subset of the images required. Each pattern is also an electrical circuit that links all images together. By linking all images electrically, the complexity and cost of the drive circuit is reduced.

The multiple operating modes of the reconfigurable keypad are under software control. As the user operates the device, the software determines which of the multiple operating modes are appropriate at any given time. The software then commands one or more of the electrical circuits to be energized, illuminating the appropriate key images. The operating software interprets the key depressions based on the operating mode and reacts accordingly. By placing the illumination of the key images and the interpretation of the key depressions under software control, it is possible to dynamically change the keypad as the user is operating the device. The device appears to “anticipate” the user's next move, creating a more enjoyable, less confusing user experience.

Additional features of the invention will become apparent herein, including the reconfigurable keypad in a handset device operable with display, cellular telephone and media player subsystems.

### BRIEF DESCRIPTION OF THE DRAWINGS

FIG. 1A is a front plane view of an embodiment of the present invention in power off mode;

FIG. 1B is a front plane view of an embodiment of the present invention in phone dialing mode;

FIG. 1C is a front plane view of an embodiment of the present invention in navigation mode;

FIG. 1D is a front plane view of an embodiment of the present invention in media player mode;

FIG. 2 is a cross-sectional view is of an embodiment of the present invention illustrating the interior of the user input device keyboard;

FIG. 3 illustrates the Reconfigurable Keyboard Device States of the user input device corresponding to a particular operation mode;

FIGS. 4A & 4B illustrate a Flowchart illustrating Main Menu operation; and

FIGS. 5A & 5B illustrate a Flowchart of the Music (media player) operations.

The descriptions illustrate embodiments thereof, from which the inventions, structure, construction and operation, and many related advantages may be readily understood and appreciated.

### DESCRIPTION OF THE EMBODIMENTS

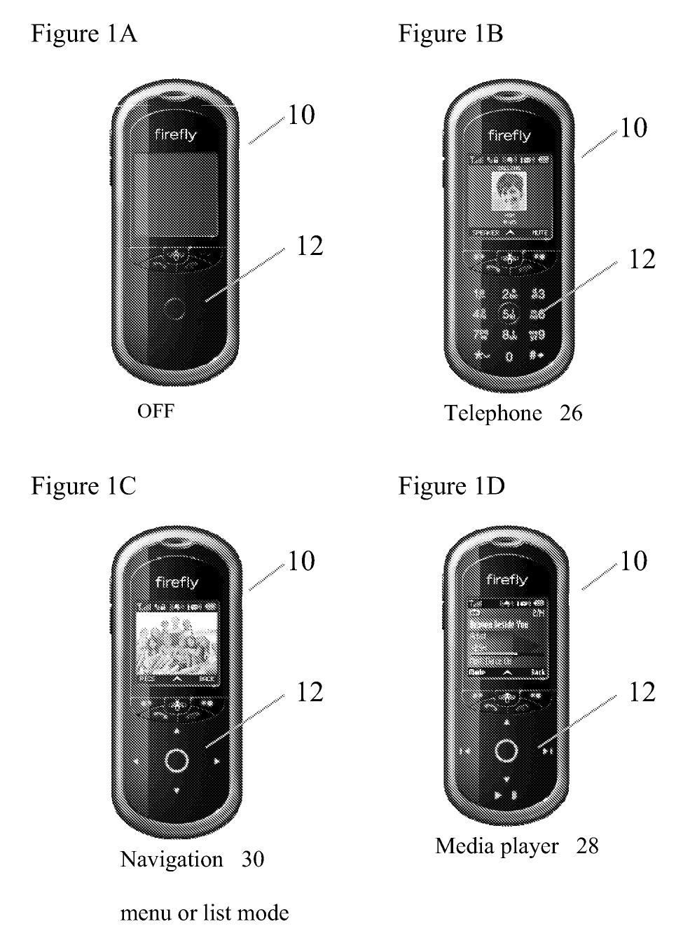

The following description is provided to enable those skilled in the art to make and use the described embodiments set forth in the best modes contemplated for carrying out the invention. Various modifications, however, will remain readily apparent to those skilled in the art. Any and all such modifications, equivalents, and alternatives are intended to fall within the spirit and scope of the present invention. Referring to Flowchart and Drawings Sheets FIG. 1-5, there is illustrated reconfigurable keypad in a handset device operable with display, cellular telephone and media player subsystems.

A user input device 10, as shown in FIG. 1 is provided that permits multiple functions to be implemented in a confined space using key images defined by a reconfigurable backlight structure under automatic software control. A described multimedia handset 10 includes a cellular telephone subsystem 26, a media player subsystem 28, and a navigation subsystem 30 on the handset 10. An information processor 14 controls the cellular telephone subsystem 26, the media player subsystem 28 and the navigation subsystem 30 in operating modes configuring the cellular telephone subsystem 26 of the handset 10 in a telephone mode, configuring the display in a navigation, menu, or list mode 30, or configuring the media player subsystem 28 of the handset 10 in a media player mode. The reconfigurable keypad 12 as shown in FIG. 3 generates multiple patterns in association with an array of keys responsive to the information processor 14 in each of the operating modes for providing one of a numeric keypad state, a navigation keypad state, and a media player keypad state automatically generated with the operating modes of the information processor 14. The decision of which of the EL patterns are active at any given time is not explicitly determined by the user. The operating mode of the keypad 12 is automatically determined by the device software, based on the application currently running on the device 10 and/or the application that the software determines will be running next. The reconfigurable keypad method in the handset device 10 advantageously employs information processing controlling the plurality of subsystems 26, 28, and 30. The information processing includes operating modes configuring a first of the plurality of subsystems in a first mode, configuring a second of the plurality of subsystems in a second mode, or configuring the display in a navigation, menu or list mode. Accordingly multiple patterns are generated in association with the array of keys responsive to the information processing step in each of the operating modes for providing one of a numeric keypad state, a media control keypad state, and a navigation keypad state automatically generated with the operating modes of the information processing step.

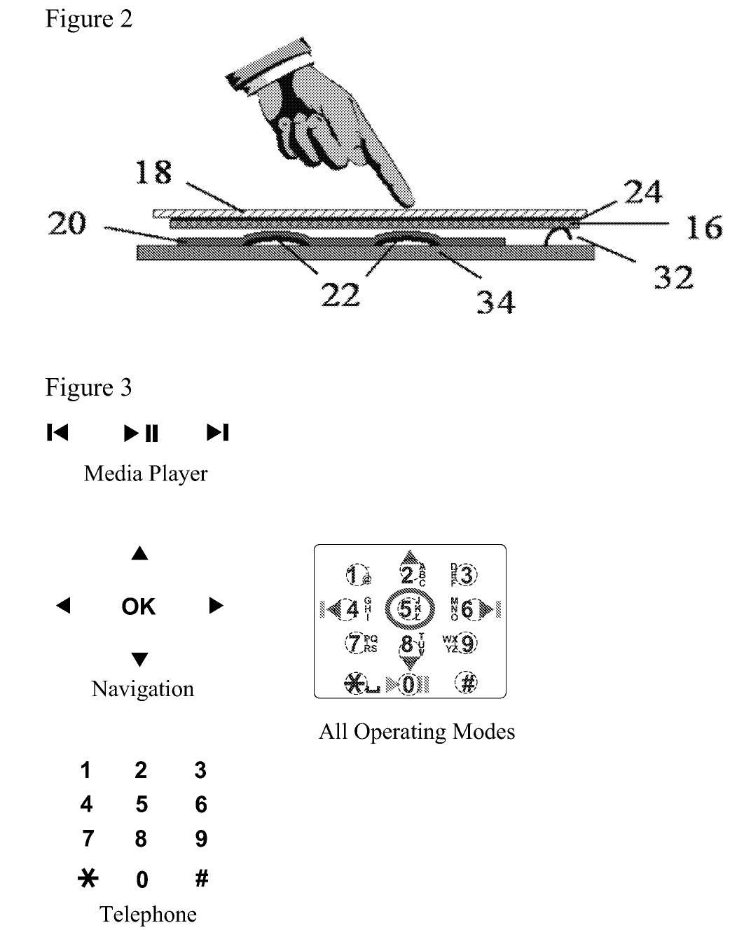

The reconfigurable keypad 12 is constructed of several layers of materials used to provide mechanical protection, key depression, and the EL panel 16 itself as shown in FIG. 2.

The top (outermost) layer 18 is a protective, transparent plastic film that the user's finger presses on. This must be durable and resistant to water and oil in order to protect the electrical circuitry or the information processor 14 beneath it, but must also be transparent so the key images can be easily seen by the user. In the present embodiment, the outer housing 16 is tinted slightly black to further block visibility of any patterns that are not active. If the outer plastic housing 18 was fully transparent, all three of the patterns would be visible all the time, regardless of whether they were electrically active or not. Tinting of the plastic housing 18 is critical for an aesthetically pleasing appearance.

The EL panel 16 is a thin, flexible polymer sheet that contains multiple patterns for the key images as shown in FIG. 3. These patterns must be designed such that only those images that are visible at the same time are electrically and physically connected. The EL panel 16 is assembled directly beneath the outermost plastic layer 18 through the use of a clear double-sided adhesive 24. Beneath the EL panel 16 is an opaque plastic sheet 20 containing the metal popples 22 that provide mechanical feedback and act as an electrical switch. The popples 22 are thin metal domes, typically 3-4 mm in diameter, placed directly on the circuit board 34. These domes 22 are sufficiently thin that when a force is applied to the top of the dome 22, the dome 22 will “pop” as the dome 22 inverts itself, similar to the pop heard when a vacuum-sealed metal lid is loosened for the first time. When the force is removed, the dome 22 “pops” back to its original shape, ready for the next key depression. The information processor is located 14 on the circuit board 34 and is connected to the EL panel 16 by an EL contact 32.

The EL panel 16 provides multiple patterns, in this case three patterns, which are used for each operating configuration of the device 10.

The first operating mode shown in FIG. 3 is a Media Player provided by the media player subsystem 28 and used for playing either music or video tracks. In this mode of operation, the keypad 12 must provide control symbols similar to those found on an MP3 player, VCR or DVD player. These functions include Reverse, Fast Forward, Play and Pause.

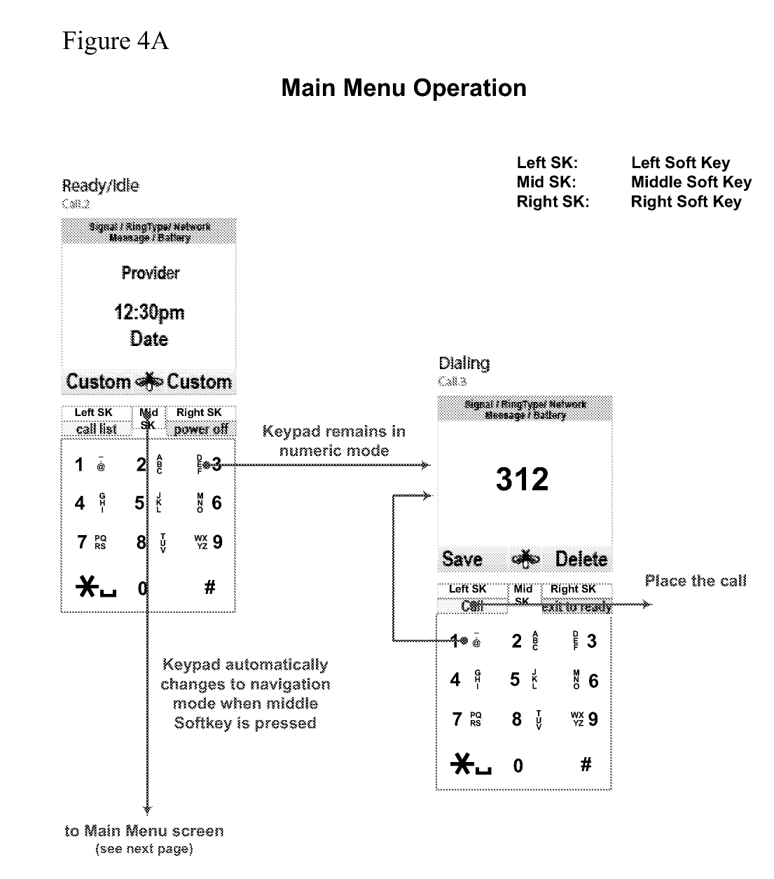

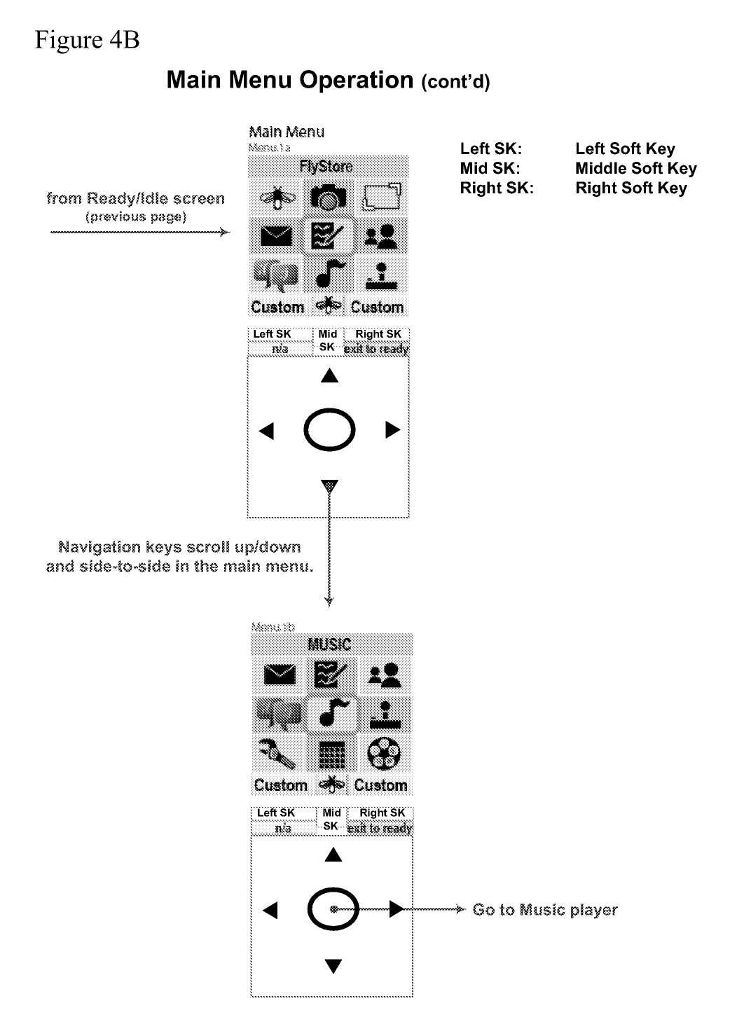

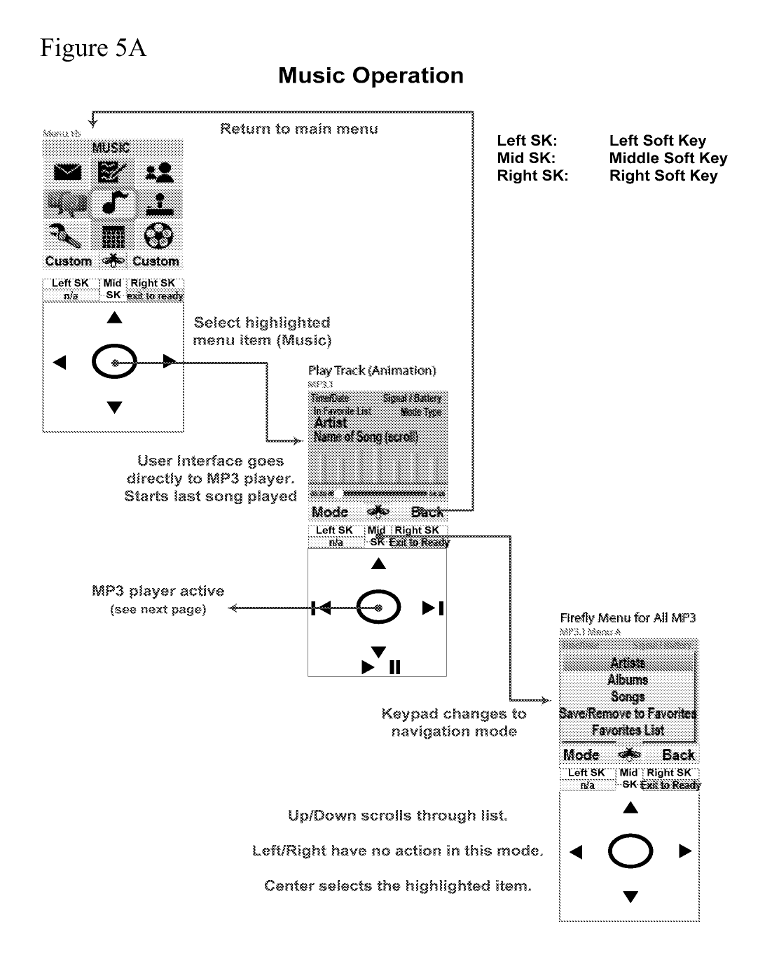

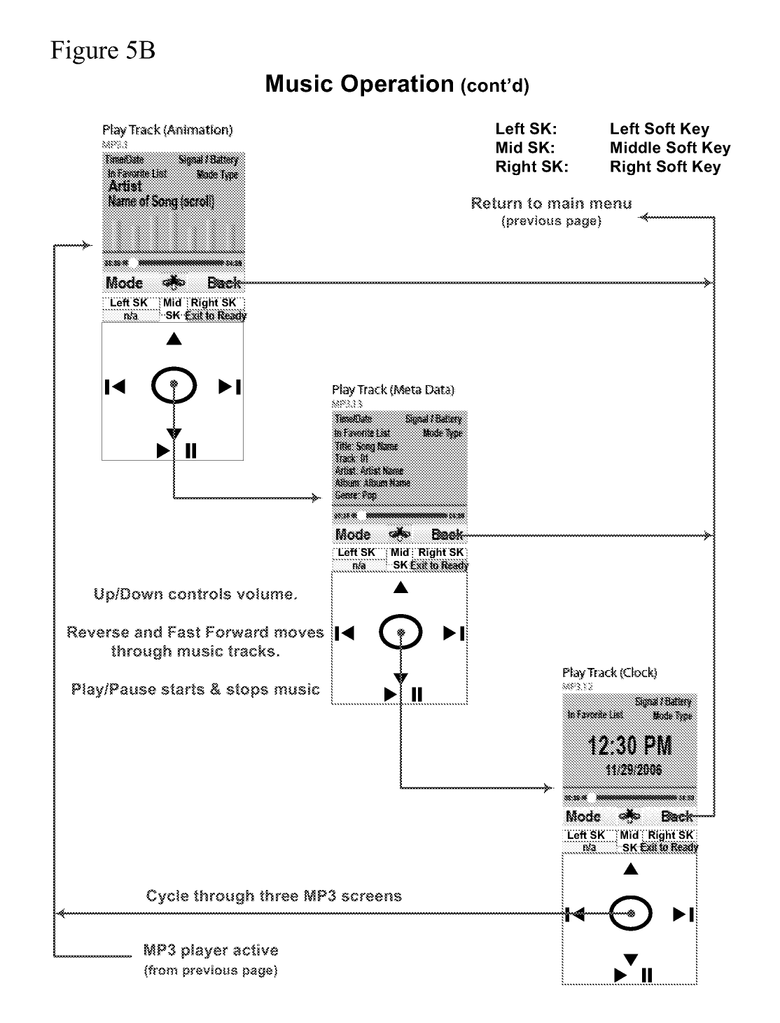

The Navigation Mode requires Up, Down, Left, Right and a center Select (OK) key. In many applications, the center OK label is removed, leaving just a circle for the user to press once the selection is highlighted. FIGS. 4A & 4B illustrate a Flowchart illustrating Main Menu operation. FIGS. 5A & 5B illustrate a Flowchart of the Music (media player) operations. There are three keypads described. The keypads change automatically depending on what the User is doing. When Phone is On, the keypad will go dark when it is not being used in order to save power; and wakes up upon any key being pressed.

The Telephone Mode provided by the telephone subsystem 26 as seen in FIG. 3 has the key layout shown. A minimum of 12 key locations are required to implement this function.

Based on these three configurations, the minimum number of key locations and therefore the minimum number of popples 22 is 12. All three configurations are then overlaid to provide appropriate functionality using only 12 popple 22 locations.

The resulting EL patterns, along with the popple 22 locations are shown in FIG. 3 and a full pattern that is electrically connected together and is therefore switched on and off at the same time. Each of these patterns must be electrically isolated from the other patterns, therefore, they cannot physically touch one another. One or all of the patterns can be illuminated, based on the operating mode. Individual patterns are fully functional operating modes of the device. Having a small number of patterns reduces the cost of the driver circuitry and the cost of assembly.

Popple 22 locations are shown with dashed circles. It should be noted that the popple 22 locations at the 2, 4, 6 and 8 digits are skewed away from the center of the digits in order to provide uniform key depression for all three operating subsystems; telephone keypad 26, navigation 30 and media player 28. FIGS. 4A, 4B and FIGS. 5A, 5B illustrate Flowcharts for Main Menu operations and the Music (media player) operations. As described the device permits multiple functions to be implemented by a reconfigurable backlight structure under automatic software control. The keypads change automatically depending on what the user is doing with the device, widely varying keypad functionality can be realized without increased the size or number of key locations. For example, from FIG. 4A, the Main Menu Operations proceed from the Ready/Idle display at Call 2 to the Dialing display at Call 3 with the keypad remaining in its numeric mode. The Main Menu Operations continued at FIG. 4B proceeds from the Ready/Idle screen to the Main Menu display Menu 1a, with the Menu/Games Keypad, pressing the arrows scrolls to and highlights items in the display area; and pressing the Select circle in the middle of the display selects an option. The Navigation keys further illustrated at FIG. 5A in Menu 1b scroll up/down and side-to-side in the Main Menu, from which pressing the Select circle in the middle of the display selects the Music player to proceed to the media player operations. At FIG. 5A the music operations proceed from Menu 1b showing the main menu, e.g., to Play Track (Animation) MP3 1 and to MP3 1 Menu A as illustrated for all MP3 keypad operation via navigation mode. At FIG. 5B the music operation continues from Play Track (Animation) MP3-1 and proceeds between Play Track (Clock) MP3-2 and the Play Track (Meta Data) MP3-3 screens to cycle through these three exemplary MP3 screens via the described navigation mode music operations as illustrated. In the Music/Movies Keypad, pressing the Fast forward/reverse arrows moves from one selection display to the next; press and hold to fast forward/reverse within a song or video; press the Select circle to select an option; press Play/Pause to play or pause a song or video. In the Phone Keypad, the User uses the Phone keypad to dial the number to call; type a name to add to your contact lists; or type a short message; press a number to type a number; and press a key quickly to type a letter.

The decision of which of the EL patterns are active at any given time is not explicitly determined by the user. The operating mode of the keypad 12 is automatically determined by the device software, based on the application currently running on the device 10 and/or the application that the software determines will be running next. For instance, while selecting a game from a menu list the software will enable the Navigation Mode of the EL keypad 12. Once the game is running it may dynamically switch between all three modes of keypad operation, depending on the requirements of the game. Another example is when navigating the main menu, the EL keypad 12 will be in Navigation Mode but will automatically change to Media Player Mode if music is selected and a song is playing. Even within the music player subsystem 28, the EL keypad 12 operating mode will automatically change from Media Player Mode to Navigation Mode (subsystem 28 to subsystem 30) if the user moves from listening to a song to browsing the list of albums. This is a completely unique and novel implementation of this functionality.

A significant operational challenge to a light-emitting keypad is the ability to be easily viewed indoors where ambient light is relatively low, as well as in direct sunlight where the incident light from the sun is far more powerful than the EL light source.

In the typical indoor viewing scenario, the light emitted from the EL panel 16 is sufficiently powerful to overcome the ambient light in the room. The user sees only the keypad configuration 12 that is currently active, as described in the previous page.

The other keypad configurations are hidden due to two factors. The other EL patterns are not energized and therefore do not emit light, and the outer plastic housing 18 is only partially transparent.

In the case of outdoor viewing in direct sunlight, the EL panel 16 cannot output more visible energy than the sun. The EL panel 16 is overwhelmed by the sun which makes it impossible to illuminate individual operating modes of the keypad 12. However, we still want the user to be able to locate the key locations so that they can continue to operate the device. This is accomplished through two additional design constraints on the outer plastic housing and the EL panel 16. The first is the outer film 18 must be partially transparent. For best sunlight visibility, the film should be 100% transparent; however, the optimal design criteria for use in both environments are 87% transparent. The second is the default color of the EL panel, i.e. the color when not energized, must be as light as possible, ideally white. A light color is more effective as a reflector of sunlight, which is the desired effect. In the present embodiment, the color is a very light blue.

In the present embodiment, the sunlight is passing through the outer film 18, reflecting off the light blue EL panel 16, and then passing back out through the outer film 18 to the user's eye.

Sunlight viewing is a fully passive mode of operation. The brighter the sunlight, the brighter the keypad image 12 appears to the user. As sunlight becomes less intense, the reflected image becomes dim and the light emitting properties of the EL panel 16 are able to overpower the reflected sunlight, reverting back to the individual images of the keypad 12.

While it is somewhat undesirable for the user to see all operating modes of the keypad, since the user has already experienced the multiple operating modes the user can readily adapt to this environment.

From the foregoing, it can be seen that there has been provided an improved reconfigurable keypad 12 in a handset device 10 operable with display 30, cellular telephone 26 and media player 28 subsystems in a device 10 of simple and economical construction. While a particular embodiment of the present invention has been shown and described, it will be obvious to those skilled in the art that changes and modifications may be made without departing from the invention in its broader aspects. Therefore, the aim in the appended claims is to cover all such changes and modifications as fall within the true spirit and scope of the invention. The matter set forth in the foregoing description and accompanying drawings is offered by way of illustration only and not as a limitation. The actual scope of the invention is intended to be defined in the following claims when viewed in their proper perspective based on the prior art.

What is claimed is:

1. A multimedia handset, comprising:
a cellular telephone subsystem;
a media player subsystem;
a display on the housing of the handset;
an information processor for controlling the cellular telephone subsystem, the media player subsystem and the display, the information processor comprising operating modes configuring the cellular telephone subsystem of the handset in a telephone mode, configuring the display in a navigation, menu or list mode, or configuring the media player subsystem of the handset in a media player mode; and
a reconfigurable keypad for generating multiple patterns in association with an array of keys responsive to the information processor in each of the operating modes for providing one of a numeric keypad state, a navigation keypad state, and a media player keypad state automatically generated with the operating modes of the information processor.

2. A multimedia handset as recited in claim 1, comprising a soft-key user input positioned relative to the display.

3. A multimedia handset as recited in claim 1, wherein the reconfigurable keypad comprises multiple patterns at least one of which is used for each of the operating modes.

4. A multimedia handset as recited in claim 3, wherein the multiple patterns comprise one or more light emitting elements.

5. A multimedia handset as recited in claim 3, wherein the multiple patterns comprise an EL panel.

6. A multimedia handset as recited in claim 3, wherein the multiple patterns are positioned atop the array of keys, each key comprising a switching element that may be activated by user contact with at least one of the multiple patterns.

7. A multimedia handset as recited in claim 6, wherein the switching elements comprise mechanical switches including a plurality of momentary switch elements, or mechanical popple elements.

8. A multimedia handset as recited in claim 6, wherein the switching elements comprise a twelve-key ITU standard telephone keypad, and at least one of the multiple patterns comprises a twelve-key ITU standard telephone keypad pattern.

9. A multimedia handset as recited in claim 8, wherein at least one of the multiple patterns comprises a navigation mode, up, down, left, right and select image.

10. A multimedia handset as recited in claim 8, wherein at least one of the multiple patterns comprises a media player operating pattern comprising control symbols for play, reverse, forward or pause.

11. A multimedia handset as recited in claim 9, comprising the navigation mode in combination with a media player operating pattern comprising control symbols for play, reverse, forward or pause.

12. A handset device, comprising:
a first communications subsystem;
a second player subsystem;
a display on the housing of the handset device;
an information processor for controlling the first subsystem, the second subsystem and the display, the information processor comprising operating modes configuring the first subsystem of the handset device in a first mode, configuring the second subsystem of the handset device in a second mode, or configuring the display in a navigation mode; and
a reconfigurable keypad for generating multiple patterns in association with an array of keys responsive to the information processor in each of the operating modes for providing one of a numeric keypad state, a media control keypad state, and a navigation keypad state automatically generated with the operating modes of the information processor.

13. A handset device as recited in claim 12, comprising a soft-key user input positioned relative to the display.

14. A handset device as recited in claim 12, wherein the reconfigurable keypad comprises multiple patterns at least one of which is used for each of the operating modes.

15. A handset device as recited in claim 14, wherein the multiple patterns comprise one or more light emitting elements.

16. A handset device as recited in claim 14, wherein the multiple patterns comprise an EL panel.

17. A handset device as recited in claim 14, wherein the multiple patterns are positioned atop the array of keys, each key comprising a switching element that may be activated by user contact with at least one of the multiple patterns.

18. A reconfigurable keypad for generating multiple patterns in association with an array of keys comprising:
an information processor;
a layer comprising a surface to act as keys; and
a sheet located atop said layer, said sheet comprising multiple patterns coordinated with said layer and in conjunction with the information processor for operating as a plurality of input for the information processor; and
a film of a predetermined level of tint color located atop said sheet, with said sheet having an associated color such that the film appears transparent to incident light, and such that the film appears opaque to ambient light.

19. A reconfigurable keypad as recited in claim 18, wherein said layer comprises compressible popples to act as keys, said sheet selectively illuminates one or more of a multiplicity of patterns in relation to the keys with light illuminated for said sheet being transmissive through said film.

20. A reconfigurable keypad as recited in claim 19, wherein said sheet comprises one or more EL panels.

21. A reconfigurable keypad method in a handset device having a display on its housing with the handset device being operable with a plurality of subsystems, the method comprising:
information processing controlling the plurality of subsystems and the display, the information processing including operating modes configuring a first of the plurality of subsystems in a first mode, configuring a second of the plurality of subsystems in a second mode, or configuring the display in a navigation, menu or list mode;
providing a reconfigurable keypad with an array of keys; and
generating multiple patterns in association with the array of keys responsive to the information processing step in each of the operating modes for providing one of a numeric keypad state, a media control keypad state, and a navigation keypad state automatically generated with the operating modes of the information processing step.

22. A reconfigurable keypad method as recited in claim 21, wherein the step of generating multiple patterns comprises generating multiple patterns at least one of which is used for each of the operating modes.

23. A reconfigurable keypad method as recited in claim 22, wherein the step of generating multiple patterns comprises selectively illuminating one or more of the multiple patterns in relation to the array of keys automatically with the information processing step responsive to the operating modes.
